(19) United States
(12) Patent Application Publication
(10) Pub. No.: US 2014/0182675 A1
(43) Pub. Date: Jul. 3, 2014

(54) SOLAR CELL AND PRODUCTION METHOD FOR SOLAR CELL

(71) Applicant: SANYO Electric Co., Ltd., Osaka (JP)

(72) Inventors: Nozomu TOKUOKA, Osaka (JP); Yoshikazu IBARA, Gifu (JP)

(73) Assignee: SANYO Electric Co., Ltd., Osaka (JP)

(21) Appl. No.: 14/200,866

(22) Filed: Mar. 7, 2014

Related U.S. Application Data
(63) Continuation of application No. PCT/JP2012/057709, filed on Mar. 26, 2012.

(30) Foreign Application Priority Data
Nov. 18, 2011 (JP) PCT/JP2011/076623

(51) Int. Cl. H01L 31/0224

(52) U.S. Cl. CPC H01L 31/022425
USPC 136/256

(57) ABSTRACT

A solar cell, comprising: a photoelectric conversion unit; a transparent conductive layer comprising a transparent conductive oxide, and formed upon the main surface of the photoelectric conversion unit; and a finger section and a bus bar section that are formed upon the transparent conductive layer. The transparent conductive layer has particles on a contact surface where the finger section and the bus bar section are formed. The particle diameter of the particles is, for example, 10-200 nm.

### CROSS-REFERENCE TO RELATED APPLICATION

The present application is a continuation under 35 U.S.C. §120 of PCT/JP2012/057709, filed Mar. 26, 2012, which is incorporated herein by reference and which claimed priority to PCT/JP2011/076623 filed. Nov. 18, 2011. The present application likewise claims priority under 35 U.S.C. §119 to PCT/JP2011/076623 filed Nov. 18, 2011, the entire content of which is also incorporated herein by reference.

### TECHNICAL FIELD

The present invention relates to a solar cell, and a method of manufacturing a solar cell.

### BACKGROUND ART

A solar cell comprises a transparent conductive layer which is formed over a primary surface of a photoelectric conversion unit, and a collecting electrode which is formed over the transparent conductive layer (refer to Patent Document 1). Patent Document 1 discloses a solar cell having a low resistance region for a portion, of the transparent conductive layer, in contact with the collecting electrode.

### RELATED ART REFERENCES

### Patent Document

[Patent Document 1] JP 2000-58888 A

### DISCLOSURE OF INVENTION

### Technical Problem

Because there is a possibility that the collecting electrode may be peeled off from the transparent conductive layer, improvement in contact strength between the collecting electrode and the transparent conductive layer is desired.

### Solution to Problem

According to one aspect of the present invention, there is provided a solar cell comprising: a photoelectric conversion unit; a transparent conductive layer formed over a primary surface of the photoelectric conversion unit; and a collecting electrode formed over the transparent conductive layer, wherein the transparent conductive layer has particles on a surface thereof.

According to another aspect of the present invention, there is provided a solar cell comprising: a photoelectric conversion unit; and an electrode formed over a primary surface of the photoelectric conversion unit, wherein the electrode comprises: a pillar-like crystal layer that is formed over the primary surface of the photoelectric conversion unit and that is transparent and conductive; a non-pillar-like crystal layer that is formed over the pillar-like crystal layer and that is transparent and conductive; and a collecting electrode that is formed over the non-pillar-like crystal layer.

According to another aspect of the present invention, there is provided a solar cell comprising: a photoelectric conversion unit; and an electrode formed over a primary surface of the photoelectric conversion unit, wherein the electrode comprises: a high-density layer that is formed over the primary surface of the photoelectric conversion unit and that is transparent and conductive; a low-density layer that is formed over the high-density layer, that has a lower density than the high-density layer, and that is transparent and conductive; and a collecting electrode that is formed over the low-density layer.

According to another aspect of the present invention, there is provided a method of manufacturing a solar cell, comprising: forming a transparent conductive layer formed with a transparent conductive oxide over a primary surface of a photoelectric conversion unit; reducing the transparent conductive oxide at a portion, of a surface of the transparent conductive layer, over which a collecting electrode is to be formed, to form particles; and then forming the collecting electrode over the portion.

According to another aspect of the present invention, there is provided a method of manufacturing a solar cell, comprising: forming a transparent conductive layer formed with a transparent conductive oxide over a primary surface of a photoelectric conversion unit; reducing the transparent conductive oxide at a portion, of a surface of the transparent conductive layer, over which a collecting electrode is to be formed, to form a non-pillar-like crystal layer; and a step of then forming the collecting electrode over the portion, wherein, in the step of forming the collecting electrode, the transparent conductive oxide is thermally treated before or after the non-pillar-like crystal layer is formed, to form a pillar-like crystal layer in portions other than the non-pillar-like crystal layer.

According to another aspect of the present invention, there is provided a method of manufacturing a solar cell, comprising: forming a transparent conductive layer formed with a transparent conductive oxide over a primary surface of a photoelectric conversion unit; reducing the transparent conductive oxide at a portion, of a surface of the transparent conductive layer, over which a collecting electrode is to be formed, to form a low-density layer; and a step of then forming a collecting electrode over the portion, wherein, in the step of forming the collecting electrode, the transparent conductive oxide is thermally treated before or after the low-density layer is formed, to forma high-density layer having a higher density than the low-density layer in portions other than the low-density layer.

### Advantageous Effects of Invention

According to the solar cell and the manufacturing method thereof of various aspects of the present invention, contact strength between the transparent conductive film and the collecting electrode can be improved.

### BRIEF DESCRIPTION OF DRAWINGS

FIG. 1 is a plan view of a solar cell according to a first preferred embodiment of the present invention, viewed from the side of a light receiving surface.

FIG. 2 is a diagram schematically showing a part of a cross section along an A-A line of FIG. 1.

FIG. 3 is an enlarged view of a B part of FIG. 2.

FIG. 4 is a plan view schematically showing a contact surface of a transparent conductive layer in a solar cell according to the first preferred embodiment of the present invention.

FIG. 5 is a diagram schematically showing an example manufacturing process of a solar cell according to the first preferred embodiment of the present invention.

FIG. 6 is a plan view schematically showing a contact surface of a transparent conductive layer in a solar cell according to an alternative configuration of the first preferred embodiment of the present invention.

FIG. 7 is a diagram schematically showing an example manufacturing process of a solar cell according to an alternative configuration of the first preferred embodiment of the present invention.

FIG. 8 is a diagram schematically showing a cross section of a transparent conductive layer and a nearby region thereof in a solar cell according to a second preferred embodiment of the present invention.

FIG. 9 is a diagram schematically showing an example manufacturing process of a solar cell according to the second preferred embodiment of the present invention.

FIG. 10 is a diagram schematically showing a cross section of the transparent conductive layer and a nearby region thereof in a solar cell according to a third preferred embodiment of the present invention.

FIG. 11 is a diagram schematically showing an example manufacturing process of a solar cell according to the third preferred embodiment of the present invention.

FIG. 12 is a cross sectional diagram schematically showing an alternative configuration of a photoelectric conversion unit in a solar cell according to a preferred embodiment of the present invention.

FIG. 13 is a cross sectional diagram schematically showing another alternative configuration of a photoelectric conversion unit in a solar cell according to a preferred embodiment of the present invention.

### DETAILED DESCRIPTION

Preferred embodiments of the present invention will now be described in detail with reference to the drawings.

The present invention is not limited to the preferred embodiments described below. In addition, the drawings referred to in the preferred embodiments are schematically shown, and the sizes and ratios of the constituent elements drawn in the figures may differ from the actual structures. The specific size, ratio, etc. should be determined in consideration of the description below.

In the present specification, the description of “a second object (for example, a transparent conductive layer)” being “formed (provided, existing, or the like) over a first object (for example, a primary surface of a photoelectric conversion unit)” is not intended to include only the case where the first and second objects are formed in direct contact with each other, unless particularly specified. In other words, such a description includes a structure where other objects exist between the first and second objects.

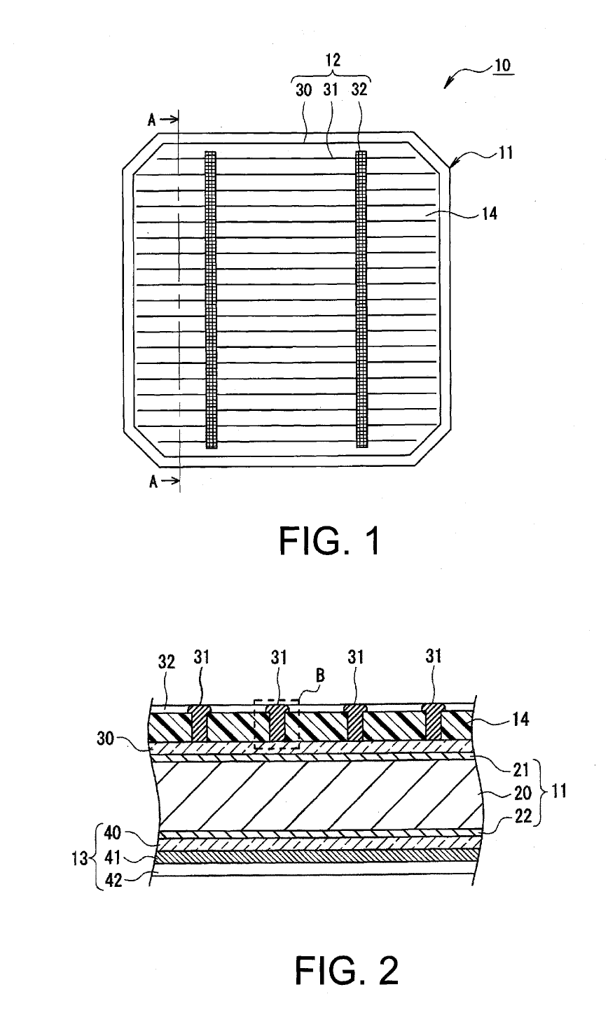

With reference to FIGS. 1 and 2, a structure of a solar cell 10 according to a first preferred embodiment of the present invention will now be described in detail.

FIG. 1 is a plan view of the solar cell 10 viewed from the side of a light receiving surface. FIG. 2 is a diagram showing a part of a cross section along an A-A line in FIG. 1, and shows a cross section cutting the solar cell 10 in the thickness direction along a direction orthogonal to a finger unit 31.

The solar cell 10 has a photoelectric conversion unit 11 which receives the solar light and generates carriers, a light receiving surface electrode 12 formed over the light receiving surface of the photoelectric conversion unit 11, and a back surface electrode 13 formed over a back surface of the photoelectric conversion unit 11. In the solar cell 10, the carriers generated at the photoelectric conversion unit 11 are collected by the light receiving surface electrode 12 and the back surface electrode 13.

Here, the “light receiving surface” refers to a primary surface through which the solar light primarily enters the solar cell 10 from outside. For example, of the solar light entering the solar cell 10, more than 50% and up to 100% of the solar light enters from the side of the light receiving surface. The “back surface” refers to a primary surface opposite to the light receiving surface. Surfaces along the thickness direction of the solar cell 10 and which are perpendicular to the primary surface are side surfaces.

The photoelectric conversion unit 11 has, for example, a semiconductor substrate 20, an amorphous semiconductor layer 21 formed over the side of the light receiving surface of the substrate 20, and an amorphous semiconductor layer 22 formed over the side of the back surface of the substrate 20. The amorphous semiconductor layers 21 and 22 respectively cover the entire regions of the light receiving surface and the back surface (including a state which can be considered substantially the entire region, for example, a state where 95% of the light receiving surface is covered, similarly applicable in the following description) of the substrate 20.

A specific example of the substrate 20 is an n-type monocrystalline silicon substrate. The amorphous semiconductor layer 21 has a layered structure in which, for example, an i-type amorphous silicon layer, and a p-type amorphous silicon layer are sequentially formed. The amorphous semiconductor layer 22 has a layered structure in which, for example, an i-type amorphous silicon layer and an n-type amorphous silicon layer are sequentially formed. Alternatively, the photoelectric conversion unit 11 may have a structure in which an i-type amorphous silicon layer and an n-type amorphous silicon layer are sequentially formed over the light receiving surface of an n-type monocrystalline silicon substrate, and an i-type amorphous silicon layer and a p-type amorphous silicon layer are sequentially formed over the back surface of the n-type monocrystalline silicon substrate.

The light receiving surface and the back surface of the substrate 20 preferably have a texture structure (not shown). The texture structure refers to a surface unevenness structure which inhibits surface reflection and increases an amount of light absorption of the photoelectric conversion unit 11. The height of the unevenness of the texture structure is about 1 μm-15 μm. Because the thicknesses of the amorphous semiconductor layers 21 and 22 and transparent conductive layers 30 and 40 to be described later are a few nanometers—a few hundreds of nanometers, the unevenness of the texture structure also appears on the transparent conductive layers 30 and 40.

The light receiving surface electrode 12 includes a transparent conductive layer 30 formed over the light receiving surface of the photoelectric conversion unit 11. The transparent conductive layer 30 (and also the transparent conductive layer 40) is formed with a transparent conductive oxide (hereinafter referred to as “TCO”) in which, for example, a metal oxide such as indium oxide (In₂O₃) and zinc oxide (ZnO) is doped with tin (Sn), antimony (Sb), or the like. The transparent conductive layer 30 (and also the transparent conductive layer 40) may cover the entire region over the amorphous semiconductor layer 21, but in the configuration shown in FIG. 1, the transparent conductive layer 30 covers the entire region over the amorphous semiconductor layer 21 other than an end periphery section. Thicknesses of the transparent conductive layers 30 and 40 are preferably about 30 nm-500 nm, and particularly preferably about 50 nm-200 nm.

The light receiving surface electrode 12 includes, as a collecting electrode which collects carriers through the transparent conductive layer 30, a plurality (for example, 50) of finger sections 31 formed over the transparent conductive layer 30. In the present embodiment, in addition, the light receiving surface electrode 12 includes a plurality (for example, 2) of bus bar sections 32 formed over the transparent conductive layer 30, extending in a direction intersecting the finger sections 31. The finger section 31 is thin-line electrode formed in a wide range over the transparent conductive layer 30. The bus bar section 32 is an electrode which collects carriers from the finger sections 31, and is an electrode, for example, to which a wire member is connected when the solar cell 10 is made into a module.

In the present embodiment, the finger section 31 and the bus bar section 32 are plated electrodes formed by electroplating. The finger section 31 and the bus bar section 32 may hereinafter be collectively called a “collecting electrode” or a “plated electrode”. The plated electrode is formed over a portion over the transparent conductive layer 30 in which a coating layer 14 is not formed. The plated electrode is formed, for example, with a metal such as nickel (Ni), copper (Cu), silver (Ag), or the like, and preferably has a layered structure of a nickel plated layer and a copper plated layer.

Over the transparent conductive layer 30, an insulating coating layer 14 is formed. The coating layer 14 is preferably formed over the entire region over the light receiving surface other than the region in which the plated electrode is formed, and in the present embodiment is also formed over the end periphery section of the amorphous semiconductor layer 21. A thickness of the coating layer 14 is, for example, 20 μm-30 μm, and is slightly thinner than the thickness of the plated electrode. A material forming the coating layer 14 is preferably a photo-curing resin including an epoxy resin or the like, from the viewpoint of productivity, insulating characteristic, contact characteristic with a module encapsulation material, etc.

The back surface electrode 13 preferably includes a transparent conductive layer 40 formed over the amorphous semiconductor layer 22, a metal layer 41 formed over the entire region over the transparent conductive layer 40, and a plurality of bus bar sections 42 formed over the metal layer 41. The metal layer 41 is a thin film made of a metal material such as silver (Ag) having a high light reflectivity and a high electric conductivity. A thickness of the metal layer 41 is, for example, about 0.1 μm-5 μm. Alternatively, in the back surface electrode 13, the metal layer 41 may be replaced with a finger section, and the finger section and the bus bar section 42 may be formed through electroplating.

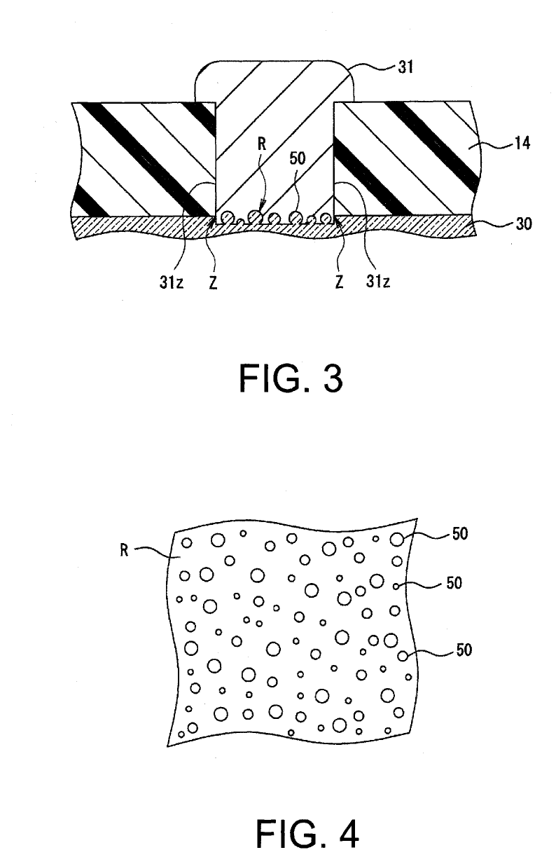

A structure of the transparent conductive layer 30 will now be further described in detail with reference to FIGS. 3 and 4.

FIG. 3 is a diagram showing a cross section near a surface of the transparent conductive layer 30 (B-part enlarged diagram of FIG. 2) enlarged, and FIG. 4 is a plan view showing a contact surface R of the transparent conductive layer 30.

The transparent conductive layer 30 has a plurality of particles on a surface thereof (refer to FIG. 3). Preferably, the particles 50 selectively exist on a contact surface R which is a contact portion with the collecting electrode, of the surface of the transparent conductive layer 30. On the other hand, preferably, the particles 50 do not exist in portions other than the contact surface R, that is, the portions where the solar light is received.

The particles 50 protrude from the surface of the transparent conductive layer 30. The particles 50 have a shape with a curved surface such as a dome shape, a semispherical shape, a spherical shape, or a spindle shape, and in particular, many particles having the semispherical shape or the spherical shape exist. As will be described later in detail, the particles 50 can be formed by reducing the TCO forming the transparent conductive layer 30. In other words, in the present embodiment, the particles 50 are formed from a part of the transparent conductive layer 30, and may therefore be also referred to as particulate protrusions.

In the present embodiment, the composition of the particles 50 is a reduction product of TCO. For example, when the TCO is a metal oxide having the primary component of indium oxide (In₂O₃), the composition of the particles 50 is indium oxide that is richer in indium compared to In₂O₃ forming the portions other than the contact surface R, or In.

A particle diameter D of the particle 50 is preferably greater than or equal to 10 nm and less than or equal to 200 nm. At least the average particle diameter of the particles 50 is preferably greater than or equal to 10 nm and less than or equal to 200 nm. The particle diameter D is measured using a scanning electron microscope (SEM) or a transmission electron microscope (TEM). When the particle 50 has a non-spherical shape such as a spindle shape, a longitudinal diameter is the particle diameter D. The longitudinal diameter of the particle 50 is defined as a long side of a circumscribed rectangle of the particle 50 defined in a two-dimensional microscopic image (a short side of the circumscribed rectangle is defined as the short-axis diameter of the particle 50). The average particle diameter is an average value of the particle diameters D, and corresponds to so-called number average diameter. The average particle diameter is an average value of the particle diameters D of all particles 50 existing in an area of 10 μm×10 μm at the contact surface R.

The particles 50 exist uniformly over the entirety of the contact surface R (refer to FIG. 4). In the example structure of FIG. 4, on the contact surface R, there is no portion where the number of particles 50 is extremely high or extremely low compared to the other portions, and the particles 50 exist randomly and uniformly. More specifically, a density K of the particles 50 is equivalent over the entirety of the contact surface R (including a substantially equivalent state such as, for example, a state where a difference in the densities K of subsections when the two-dimensional microscopic image of the contact surface R is divided into a plurality of subsections having the same area is within 5%; similarly applicable in the following description). The density K refers to a ratio of an area Ap in which the particles 50 exist with respect to an area Ar of the contact surface R, that is, K %=(Ap/Ar)×100, and can be measured using the SEM or TEM.

The density K is preferably in a range of 10%-100%, more preferably in a range of 20%-80%, and particularly preferably in a range of 25%-75%. Based on the relationship between the density K and the number average particle diameter Dn, it is possible to sufficiently improve the contact strength between the transparent conductive layer 30 and the collecting electrode while inhibiting a significant increase in the sheet resistance.

In the transparent conductive layer 30, a thickness of a portion corresponding to the contact surface R where the particles 50 exist is thinner than the thickness of the other portions. In other words, in the transparent conductive layer 30, the portion in which the reduction process of the TCO is applied is made thin.

In the transparent conductive layer 30, the sheet resistance of the contact surface R is higher than the sheet resistance of the other portions. For example, the sheet resistance of the contact surface R is higher by a factor of about 1.05 times to 5 times compared to the sheet resistance of the other portions. The sheet resistance of the contact surface R tends to become higher as the density K is increased or the number average particle diameter Dn is increased. The sheet resistance can be measured by a known method (for example, a four-point probe method).

A region immediately below the collecting electrode, that is, the contact surface R, may have a high sheet resistance. This is because the carriers flowing in the collecting electrode can be collected from an immediately below region Z (may also be considered as a boundary region between the contact surface R and the other portions) of ( [symbol] ) a side surface 31z of the collecting electrode, among the regions of the transparent conductive layer 30.

Alternatively, the particles may be provided at the surface of the transparent conductive layer 40. Because the metal layer 41 is formed over the entire region of the transparent conductive layer 40, for example, the particles may be provided over the entire region of the surface of the transparent conductive layer 40, to improve the contact strength between the transparent conductive layer 40 and the metal layer 41.

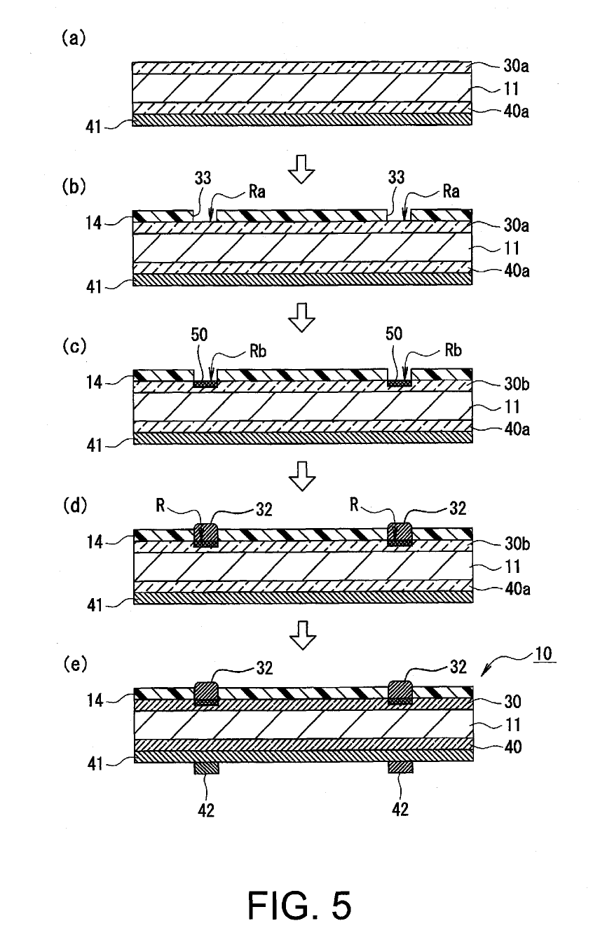

Next, with reference to FIG. 5, a manufacturing process of the solar cell 10 having the above-described structure will be described in detail. FIG. 5 is a diagram showing an example manufacturing process of the solar cell 10. In FIG. 5, a portion in which the particles 50 are formed is shown by cross hatching. In this description, it is assumed that the collecting electrode is formed by two electroplating steps, including a nickel plating step and a copper plating step using the coating layer 14 as a mask, and the bus bar section 42 is formed by screen printing using a conductive paste.

In the manufacturing process of the solar cell 10, first, the photoelectric conversion unit 11 is manufactured through a known method (the manufacturing process of the photoelectric conversion unit 11 will not be described in detail). When the photoelectric conversion unit 11 is prepared, the light receiving surface electrode 12 is formed over the light receiving surface of the photoelectric conversion unit 11, and the back surface electrode 13 is formed over the back surface of the photoelectric conversion unit 11. In the example structure shown in FIG. 5, transparent conductive layers 30a and 40a which are precursors of the transparent conductive layers 30 and 40 are formed over the light receiving surface and the back surface of the photoelectric conversion unit 11, respectively, and then the metal layer 41 is formed over the transparent conductive layer 40a (FIG. 5(a)). The transparent conductive layers 30a and 40a and the metal layer 41 can be formed, for example, using sputtering.

FIGS. 5(b)-5(d) show a mask formation step, a particle forming step, and an electroplating step, respectively. In the mask formation step, the coating layer 14 made of a photo-curing resin is formed over the transparent conductive layer 30a as a mask. In the mask formation step, for example, a patterned coating layer 14 is formed over the entire region of the light receiving surface. The patterned coating layer 14 may be formed through a known method. For example, the patterned coating layer 14 may be formed by forming a thin film layer made of a photo-curing resin over the light receiving surface through spin coating, spraying, or the like, and applying a photolithography technique. Alternatively, the patterned coating layer 14 may be formed through printing such as screen printing.

The coating layer 14 is patterned to expose, of the surface of the transparent conductive layer 30a, a surface Ra which is a portion over which the collecting electrode is to be formed (a surface Ra which becomes the contact surface R). That is, an opening 33 corresponding to the contact surface R is formed in the coating layer 14. In addition, the coating layer 14 also functions as a mask in the particle forming step.

The particle forming step is provided between the mask formation step and the electroplating step. The particle forming step is a step in which the TCO in the surface Ra exposed from the opening 33 is reduced, to form particles 50. When the TCO is reduced, at the initial stage of reduction, an amount of oxygen in the TCO is reduced and the sheet resistance is reduced, but in the present step, the reduction proceeds further. With such a process, the sheet resistance becomes higher than that before the reduction, and a surface Rb in which the particles 50 are deposited (transparent conductive layer 30b) is formed. For example, when the TCO is the indium oxide (In₂O₃), particles 50 having a higher ratio of indium (In) are deposited. In other words, the particle forming step is a step in which the reduction process is executed until the particles 50 are deposited.

The method of the reduction process is not particularly limited, so long as the method allows selective reduction of the TCO at the surface Ra to deposit the particles 50. For example, reduction by a hydrogen plasma process or electrolytic reduction may be employed. The former is a gas phase reduction method and the latter is a liquid phase reduction method. When the electrolytic reduction is executed, for example, an aqueous solution of ammonium sulfate is used as the electrolytic solution, the photoelectric conversion unit 11 over which the coating layer 14 is formed is used as a cathode, and a platinum plate is used as an anode. The photoelectric conversion unit 11 and the platinum plate are immersed in the electrolytic solution, and a current is applied therebetween. A negative electrode, for example, of a power supply device is connected to the photoelectric conversion unit 11, at apart of the surface Ra that is exposed from the opening 33.

A particle diameter D and a density K of the particles 50 can be adjusted, for example, by an amount of applied current (current×time). As the amount of current is increased, typically, the particle diameter D is increased and the density K is increased.

In the electroplating step, electroplating is executed using the photoelectric conversion unit 11 over which the coating layer 14 is formed as the cathode, and using a nickel plate as the anode. A negative electrode, for example, of a power supply device is connected to the photoelectric conversion unit 11 at a part of the surface Rb exposed from the opening 33. The electroplating is executed in a state where the back surface is insulated and covered such that the metal plated layer is not deposited over the back surface of the photoelectric conversion unit 11 (for example, an insulating resin layer covering the back surface is formed and then removed after the electroplating step), by immersing the photoelectric conversion unit 11 and the nickel plate in the plating solution and applying a current therebetween. As the plating solution, a known nickel plating solution containing nickel sulfate or nickel chloride may be used. In this manner, a nickel plated layer is formed over the surface Rb which is exposed from the opening 33 and in which a large number of particles 50 are formed.

Then, electroplating is executed using a copper plate as the anode and a known copper plating solution containing copper sulfate or copper cyanide. In this manner, the copper plated layer is formed over the nickel plated layer which is formed earlier, and the finger section 31 and the bus bar section 32 made of the nickel plated layer and the copper plated layer are formed. The thicknesses of the metal plated layers are, for example, each about 30 μm-50 μm, and can be adjusted by the amount of applied current (current×time).

Then, the bus bar section 42 is formed over the metal layer 41 through screen printing (FIG. 5(e)). In this step, after a conductive paste (for example, silver paste) is screen-printed in a desired pattern over the metal layer 41, a solvent included in the paste is volatilized to form the bus bar section 42. The conductive paste contains, for example, a thermosetting binder resin such as an epoxy resin, a conductive filler dispersed in the binder resin such as silver or carbon, and a solvent such as butylcarbitolacetate (BCA). In other words, the bus bar section 42 is made of the binder resin in which the conductive filler is dispersed.

When the solvent in the conductive paste is volatilized and the binder resin is thermoset, for example, a thermal treatment is applied under conditions of 200° C.×60 minutes. The TCO forming the transparent conductive layers 30b and 40a is crystallized in the thermal treatment step, and the conductivity is improved. That is, the thermal treatment step is a step for removing the solvent of the conductive paste and thermosetting the binder resin, and at the same time, is an annealing step for crystallizing the TCO. Alternatively, the annealing step, that is, the formation step of the bus bar section 42, may be provided after the particle forming step and before the electroplating step.

In the manner described above, a large number of particles 50 may be provided in the contact surface R with the collecting electrode, of the surface of the transparent conductive layer 30. In other words, in the contact surface R, unevenness in the order of a few tens-a few hundreds of nanometers is formed by the particles 50, and the surface area of the contact surface R is significantly increased. Because of this, the contact area between the transparent conductive layer 30 and the collecting electrode is significantly increased, and the contact strength therebetween can be improved. On the other hand, because the particles 50 are selectively provided only in the contact surface R by the existence of the coating layer 14, generation of light reception loss due to the particles 50 can be prevented.

In addition, because the collecting electrode is formed through electroplating, the solar cell 10 can be manufactured at a lower cost compared to other methods (for example, sputtering or screen printing). Normally, the plated electrode is inferior in the contact characteristic with the transparent conductive layer compared to electrodes formed through other methods, but according to the solar cell 10, the contact strength between the plated electrode and the transparent conductive layer 30 can be improved, and the peeling of the plated electrode can be sufficiently inhibited.

Moreover, in the solar cell 10, because the particles 50 exist with a uniform density K over the entire contact surface R, the contact strength between the plated electrode and the transparent conductive layer can be tremendously improved. This configuration can be realized by reducing the TCO in the amorphous state to deposit the particles 50, and then crystallizing the TCO.

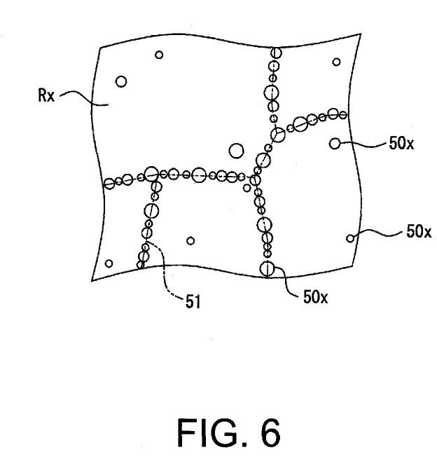

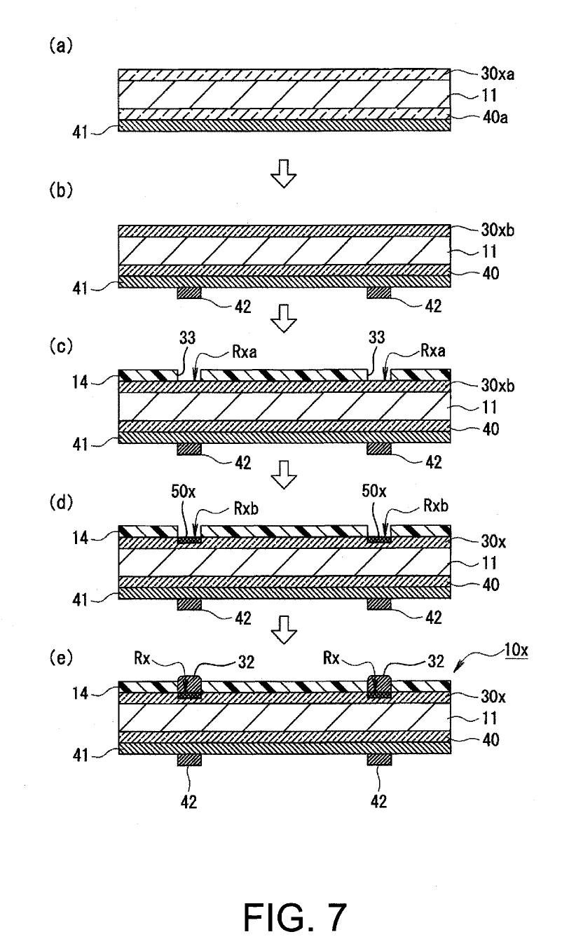

With reference to FIGS. 6 and 7, a solar cell 10x according to an alternative configuration of the solar cell 10 will now be described in detail. FIG. 6 is a plan view showing a contact surface Rx of a transparent conductive layer 30x, and FIG. 7 is a diagram showing an example manufacturing process of the solar cell 10x. In FIG. 7, a portion in which the particles 50x are formed is shown with cross hatching.

The solar cell 10x has the same structure as the solar cell 10 except for the transparent conductive layer 30x. Here, the difference from the solar cell 10 (transparent conductive layer 30x) will be described in detail, and the constituent elements similar to those of the solar cell 10 will be assigned the same reference numerals and will not be described again. The manufacturing process of the solar cell 10x differs from that of the solar cell 10 in the order of the steps, but the processing methods in each individual step are similar to those for the solar cell 10.

In the transparent conductive layer 30x, in a portion, of the contact surface Rx, in which a crystal grain boundary 51 of the TCO forming the transparent conductive layer 30x is formed, the particles 50x exist at a higher density than in the other portions (refer to FIG. 6). The crystal grain boundary 51 is formed, for example, in a mesh shape over the entire transparent conductive layer 30x. In the example configuration shown in FIG. 6, the majority of the particles 50x exist in a linear arrangement along the crystal grain boundary 51, and a small number of particles 50x exist at a portion distanced from the crystal grain boundary 51. In addition, the particles 50x existing along the crystal grain boundary 51 tend to have a larger particle diameter Dx than the particles 50x existing distanced from the crystal grain boundary 51.

The solar cell 10x having the above-described structure can be manufactured by annealing the TCO, and then reducing the crystallized TCO to deposit the particles 50x (refer to FIG. 7). Similar to the case of the first preferred embodiment, the TCO is crystallized by the thermal treatment in the formation step of the bus bar section 42 (FIG. 7(b)). In the present embodiment, the coating layer 14 is formed over the crystallized TCO, and using the coating layer 14 as a mask, a surface R×a which is to become the contact surface Rx is selectively reduced until the particles 50x are deposited (FIGS. 7 (c) and 7(d)). When the crystallized TCO is reduced, the particles 50x are selectively deposited at the crystal grain boundary 51. In other words, in portions other than the crystal grain boundary 51, the TCO tends to not be reduced. In this manner, the transparent conductive layer 30x in which the particles 50x are concentrated in the crystal grain boundary 51 can be obtained.

According to the solar cell 10x, the surface area of the contact surface Rx is increased by the particles 50x, and the contact strength between the transparent conductive layer 30x and the collecting electrode can be improved.

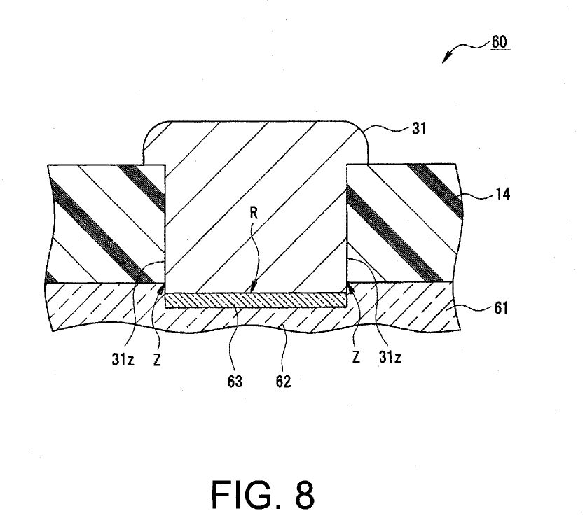

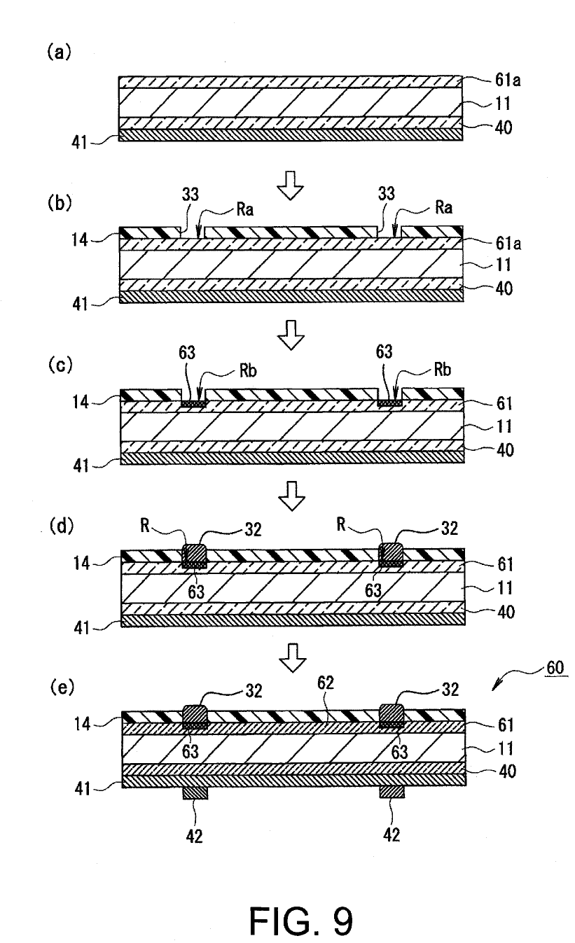

With reference to FIGS. 8 and 9, a solar cell 60 according to a second preferred embodiment of the present invention will now be described in detail.

FIG. 8 is a diagram showing a cross section of the transparent conductive layer 61 and a region nearby, and FIG. 9 is a diagram showing an example manufacturing process of the solar cell 60.

The solar cell 60 has the same structure as the solar cell 10 except for the transparent conductive layer 61. Here, the transparent conductive layer 61 will be described in detail, and the constituent elements similar to those of the solar cell 10 will be assigned the same reference numerals and will not be described again (FIGS. 1 and 2 may show the solar cell 60 when the reference numeral “30” is replaced with “61”).

In the solar cell 60, the light receiving surface electrode 12 has a pillar-like crystal layer 62 which is formed over the light receiving surface of the photoelectric conversion unit 11 and which is transparent and conductive, a non-pillar-like crystal layer 63 which is formed over the pillar-like crystal layer 62 and which is transparent and conductive, and the finger section 31 and the bus bar section 32 which are a collecting electrode formed over the non-pillar-like crystal layer 63. The pillar-like crystal layer 62 and the non-pillar-like crystal layer 63 are collectively referred to as a transparent conductive layer 61. The back surface electrode 13 has the transparent conductive layer 40, but alternatively, a pillar-like crystal layer and a non-pillar-like crystal layer similar to those over the light receiving surface electrode 12 may be provided in place of the transparent conductive layer 40.

The pillar-like crystal layer 62 is a layer in which a crystal grain boundary oriented in the same direction can be confirmed over approximately the entire region of an observation cross section by a cross sectional observation using SEM. The “approximately the entire region” includes a range which can be substantially assumed to be the entire region, for example, a region of 95% or greater of the observation cross section. In the SEM image, shading of the contrast is repeated in one direction, which appears to be a plurality of pillars arranged in the one direction or a band shape. Such a boundary of contrast shading indicates the crystal grain boundary.

The non-pillar-like crystal layer 63 is a layer in which a ratio of the crystal grain boundary oriented in different directions is greater than that of the crystal grain boundary oriented in the same direction by the cross sectional observation using SEM. In the SEM image, the portion in which the contrast shading is repeated in one direction is less than 50%, and in some cases, the portion of the regular repetition of the contrast shading cannot be recognized.

The pillar-like crystal layer 62 is a layer in which all crystal grain boundaries are in the same orientation, and exists on a side of the photoelectric conversion unit 11 in relation to the photoelectric conversion unit 11 and the light receiving surface electrode 12.

The non-pillar-like crystal layer 63 is a layer in which at least one crystal grain boundary is in the same orientation and not all of the crystal grain boundaries are in the same orientation. The non-pillar-like crystal layer 63 exists on the side of the light receiving surface electrode 12 in relation to the photoelectric conversion unit 11 and the light receiving surface electrode 12.

In the transparent conductive layer 61, the pillar-like crystal layer 62 is provided in a wider range than the non-pillar-like crystal layer 63. The non-pillar-like crystal layer 63 is preferably selectively provided, of the surface of the transparent conductive layer 61, at the contact surface R which is the contact portion with the collecting electrode and a region immediately below of the contact surface R (hereinafter also referred to as “contact surface region”). The non-pillar-like crystal layer 63 is preferably not provided at portions other than the contact surface region, where the solar light is received. In other words, the transparent conductive layer 61 in the contact surface region has a layered structure of the pillar-like crystal layer 62 and the non-pillar-like crystal layer 63, and the other portions of the transparent conductive layer 61 have a single-layer structure formed only with the pillar-like crystal layer 62.

In the present embodiment, the composition of the pillar-like crystal layer 62 is crystallized TCO, and the composition of the non-pillar-like crystal layer 63 is a reduction product of TCO. For example, when the TCO is a metal oxide having the primary composition of indium oxide (In₂O₃), the composition of the non-pillar-like crystal layer 63 is indium oxide which is richer in indium compared to In₂O₃ forming the portions other than the contact surface region or In.

A thickness of the transparent conductive layer 61 is preferably in a range of about 30 nm-500 nm, and is particularly preferably in a range of 50 nm-200 nm. A thickness of the non-pillar-like crystal layer 63 is preferably thinner than a thickness of the pillar-like crystal layer 62. More specifically, a ratio of the thickness of the non-pillar-like crystal layer 63 with respect to the thickness of the pillar-like crystal layer 62 (thickness of the non-pillar-like crystal layer 63/thickness of the pillar-like crystal layer 62) is preferably in a range of about 0.2-0.8, and particularly preferably in a range of about 0.3-0.6. For example, the thickness of the pillar-like crystal layer 62 is 80 nm and the thickness of the non-pillar-like crystal layer 63 is 20 nm. These thicknesses are average values of the lengths along the thickness direction measured by a cross sectional observation using SEM.

In the transparent conductive layer 61, the thickness of the portion in which the non-pillar-like crystal layer 63 is formed is thinner than the thickness of the other portions. In other words, in the transparent conductive layer 61, the portion in which the reduction process of the TCO is applied is made thin.

The non-pillar-like crystal layer 63 may exist over approximately the entirety of the contact surface R or a part of the contact surface R. When the non-pillar-like crystal layer 63 exists in a part of the contact surface R, that is, when the pillar-like crystal layer 62 and the non-pillar-like crystal layer 63 exist in the contact surface R, the area of the non-pillar-like crystal layer 63 is preferably 20%-80% of the area of the contact surface R, and is particularly preferably 25%-75% of the area of the contact surface R. In addition, the non-pillar-like crystal layer 63 preferably exists evenly and uniformly on the contact surface R.

In the transparent conductive layer 61, a sheet resistance of the non-pillar-like crystal layer 63 is higher than a sheet resistance of the pillar-like crystal layer 62. The sheet resistance of the non-pillar-like crystal layer 63 is higher, for example, by a factor of 1.05 times-5 times compared to the sheet resistance of the pillar-like crystal layer 62. The sheet resistance can be measured by a known method (for example, a four-point probe method).

The sheet resistance of the contact surface region may be high. This is because the carriers flowing to the collecting electrode can be collected from an immediately below region Z of the transparent conductive layer 61.

With reference to FIG. 9, a manufacturing process of the solar cell 60 having the above-described structure will now be described in detail. FIG. 9 is a diagram showing an example manufacturing process of the solar cell 60. Here, the process will be described assuming that the collecting electrode is formed by two electroplating steps, including the nickel plating step and the copper plating step using the coating layer 14 as a mask, and that the bus bar section 42 is formed by screen printing using the conductive paste.

Here, after the TCO layer of a single layer is formed, the TCO layer is reduced, to form the non-pillar-like crystal layer 63. The pillar-like crystal layer 62 is formed at the formation of the TCO layer. However, the formation method of the pillar-like crystal layer 62 and the non-pillar-like crystal layer 63 is not limited to such a method. For example, the pillar-like crystal layer 62 may be formed by thermally treating the TCO layer having the non-pillar-like crystal layer 63 after the non-pillar-like crystal layer 63 is formed.

In the manufacturing process of the solar cell 60, first, the photoelectric conversion unit 11 is manufactured by a known method (the manufacturing process of the photoelectric conversion unit 11 will not be described in detail). When the photoelectric conversion unit 11 is prepared, the light receiving surface electrode 12 is formed over the light receiving surface of the photoelectric conversion unit 11, and the back surface electrode 13 is formed over the back surface of the photoelectric conversion unit 11. In the example configuration of FIG. 9, a transparent conductive layer 61a which is a precursor of the transparent conductive layer 61 is formed over the light receiving surface of the photoelectric conversion unit 11, and the transparent conductive layer 40 is formed over the back surface of the photoelectric conversion unit 11. Then, the metal layer 41 is formed over the transparent conductive layer 40 (FIG. 9(a)). The transparent conductive layers 61a and 40 can be formed using chemical vapor deposition (CVD), for example. The film formation by the CVD is preferably executed under a temperature condition of about 200° C.-300° C., and the TCO is crystallized by the heat and the pillar-like crystal layer 62 is formed. The metal layer 41 can be formed, for example, through sputtering.

FIGS. 9(b)-9(d) show a mask formation step, a non-pillar-like crystal layer formation step, and an electroplating step. In the mask formation step, the coating layer 14 made of the photo-curing resin is formed as a mask over the transparent conductive layer 61a. In the mask formation step, a patterned coating layer 14 is formed over the entire region over the light receiving surface. The patterned coating layer 14 can be formed through a known method. For example, the patterned coating layer 14 is formed by forming a thin film layer made of a photo-curing resin over the light receiving surface through spin coating, spraying, or the like, and then applying a photolithography process. Alternatively, the patterned coating layer 14 may be formed using printing such as screen printing.

The coating layer 14 is patterned to expose a surface Ra which is a portion, of the surface of the transparent conductive layer 61a, over which the collecting electrode is to be formed (surface Ra which becomes the contact surface R). That is, in the coating layer 14, an opening 33 corresponding to the contact surface R is formed. The coating layer 14 also functions as a mask in the non-pillar-like crystal layer formation step.

The non-pillar-like crystal layer formation step is provided between the mask formation step and the electroplating step. The non-pillar-like crystal layer formation step is a step in which the TCO at the surface Ra of the transparent conductive layer 61a formed with the pillar-like crystal layer 62 exposed from the opening 33 is reduced to form the non-pillar-like crystal layer 63. When the TCO is reduced, in the initial stage of the reduction, an amount of oxygen in the TCO is reduced and the sheet resistance is reduced, but in the present step, the reduction proceeds further. With such a process, the sheet resistance becomes higher than that before the reduction, and the non-pillar-like crystal layer 63 is formed in the surface Ra and the region immediately below of the surface Ra. For example, when the TCO is indium oxide (In₂O₃), the non-pillar-like crystal layer 63 in which a ratio of indium (In) is increased is formed. In this manner, the transparent conductive layer 61 having the pillar-like crystal layer 62 and the non-pillar-like crystal layer 63 is formed.

The method of the reduction process is not particularly limited so long as the TCO in the surface Ra can be selectively reduced and the non-pillar-like crystal layer 63 can be formed. For example, reduction by a hydrogen plasma process or electrolytic reduction may be employed. The former is a gas phase reduction and the latter is a liquid phase reduction. When the electrolytic reduction is executed, for example, an aqueous solution of ammonium sulfate is used as an electrolytic solution, the photoelectric conversion unit 11 over which the coating layer 14 is formed is used as the cathode, and a platinum plate is used as the anode. The photoelectric conversion unit 11 and the platinum plate are immersed in the electrolytic solution, and a current is applied therebetween. A negative electrode, for example, of a power supply device is connected to the photoelectric conversion unit 11a at a part of the surface Ra exposed from the opening 33.

The thickness and the area in the contact surface R of the non-pillar-like crystal layer 63 can be adjusted by, for example, an amount of applied current (current×time). Typically, as the amount of current increases, the thickness and the area in the contact surface R of the non-pillar-like crystal layer 63 are increased.

In the electroplating step, the electroplating is executed using the photoelectric conversion unit 11 over which the coating layer 14 is used as the cathode and a nickel plate is used as the anode. A negative electrode, for example, of a power supply device is connected to the photoelectric conversion unit 11 at a part of the surface Rb of the transparent conductive layer 61 exposed from the opening 33. The electroplating is executed, for example, in a state where the back surface is insulated and covered such that the metal plated layer is not deposited over the back surface of the photoelectric conversion unit 11 (for example, an insulating resin layer covering the back surface is formed and then removed after the electroplating step), by immersing the photoelectric conversion unit 11 and the nickel plate in a plating solution, and applying a current therebetween. For the plating solution, a known nickel plating solution containing nickel sulfate or nickel chloride may be used. In this manner, a nickel plated layer is formed over the surface Rb exposed from the opening 33 and over which the non-pillar-like crystal layer 63 is formed.

Then, electroplating is executed using a copper plate as the anode, and a known copper plating solution containing copper sulfate or copper cyanide. In this manner, a copper plated layer is formed over the nickel plated layer which is formed earlier, and the finger section 31 and the bus bar section 32 formed with the nickel plated layer and the copper plated layer are formed. The thicknesses of the metal plated layers are each about 30 μm-50 μm, for example, and may be adjusted by an amount of applied current (current×time).

Next, the bus bar section 42 is formed over the metal layer 41 through screen printing (FIG. 9(e)). In the present step, after a conductive paste (for example, silver paste) is screen-printed over the metal layer 41 in a desired pattern, a solvent included in the paste is volatilized to form the bus bar section 42. The conductive paste contains a thermosetting binder resin such as an epoxy resin, a conductive filler dispersed in the binder resin such as silver or carbon, and a solvent such as butylcarbitolacetate (BCA). In other words, the bus bar section 42 is made of a binder resin in which the conductive filler is dispersed. When the solvent in the conductive paste is volatilized and the binder resin is thermoset, for example, a thermal treatment is executed under conditions of 200° C.×60 minutes.

Alternatively, the pillar-like crystal layer 62 may be formed by the thermal treatment during the formation of the bus bar section 42. For example, a TCO layer is formed through sputtering (under a non-heated condition), and after the non-pillar-like crystal layer 63 is formed in the above-described manner, the portions other than the non-pillar-like crystal layer 63 may be crystallized in the thermal treatment step, to form the pillar-like crystal layer 62.

In the manner described above, the non-pillar-like crystal layer 63 can be provided in the contact surface R of the transparent conductive layer 61 and the region immediately below of the contact surface, to obtain a layered structure of the pillar-like crystal layer 62 and the non-pillar-like crystal layer 63. Because the contact strength between the non-pillar-like crystal layer 63 and the collecting electrode is greater than the contact strength between the pillar-like crystal layer 62 and the collecting electrode, according to the solar cell 60 having the non-pillar-like crystal layer 63 in the contact surface R, the contact strength between the transparent conductive layer 61 and the collecting electrode can be improved.

On the other hand, the non-pillar-like crystal layer 63 has a lower transparency than the pillar-like crystal layer 62. However, because the non-pillar-like crystal layer 63 is selectively provided only in the contact surface R due to the existence of the coating layer 14, generation of light reception loss due to the non-pillar-like crystal layer 63 can be prevented.

In addition, because the collecting electrode is formed by electroplating, the solar cell 60 can be manufactured at a lower cost compared to the other methods (for example, sputtering and screen printing). Normally, the plated electrode is inferior in the contact characteristic with the transparent conductive layer compared to the electrodes formed through other methods, but according to the solar cell 60, the contact strength between the plated electrode and the transparent conductive layer 61 can be improved, and the peeling of the plated electrode can be sufficiently inhibited.

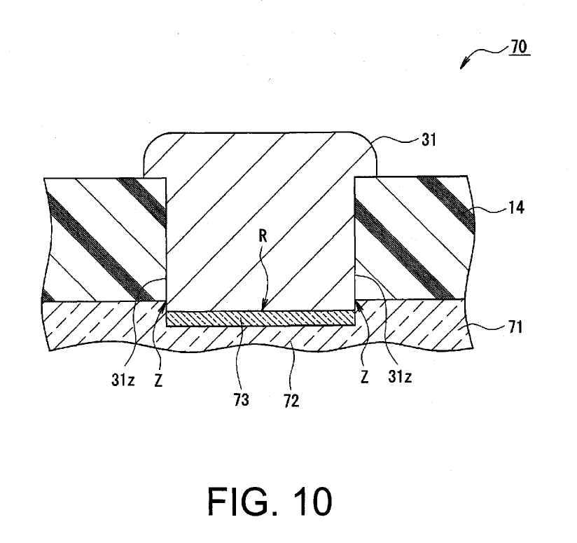

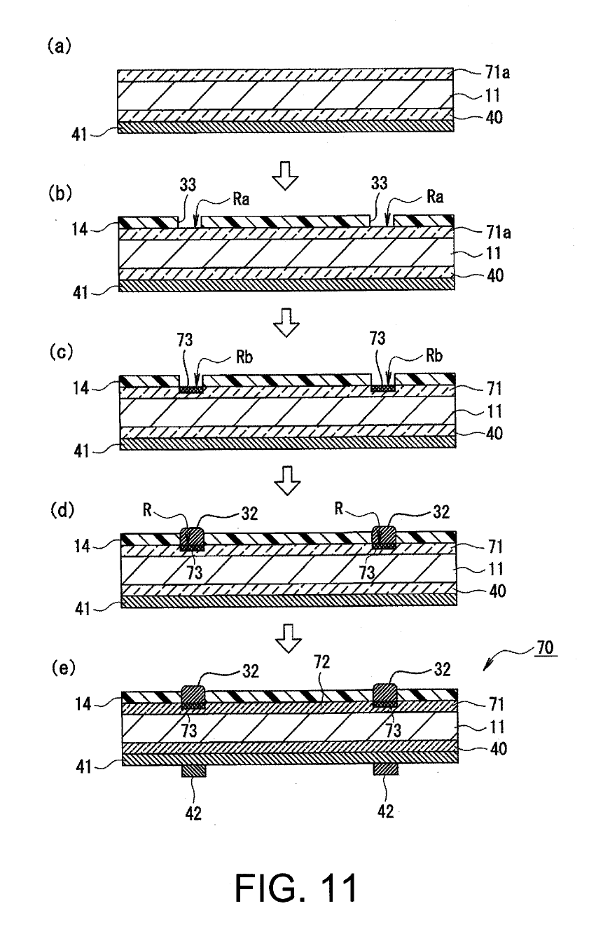

With reference to FIGS. 10 and 11, a solar cell 70 according to a third preferred embodiment of the present invention will now be described in detail.

FIG. 10 is a diagram showing a cross section of the transparent conductive layer 71 and a region nearby, and FIG. 11 is a diagram showing an example manufacturing process of the solar cell 70.

The solar cell 70 has the same structure as the solar cell 10 except for the transparent conductive layer 71. Here, the transparent conductive layer 71 will be described in detail, and the constituent elements similar to those of the solar cell 10 will be assigned the same reference numerals and will not be described again (FIGS. 1 and 2 may show the solar cell 70 if the reference numeral “30” is replaced with “71”).

In the solar cell 70, the light receiving surface electrode 12 has a high-density layer 72 which is formed over the light receiving surface of the photoelectric conversion unit 11 and which is transparent and conductive, a low-density layer 73 which is formed over the high-density layer 72, which has a lower density than the high-density layer 72, and which is transparent and conductive, and the finger section 31 and the bus bar section 32 which are a collecting electrode formed over the low-density layer 73. The high-density layer 72 and the low-density layer 73 will hereinafter be collectively called a transparent conductive layer 71. The back surface electrode 13 has the transparent conductive layer 40, but alternatively, a high-density layer and a low-density layer may be provided in place of the transparent conductive layer 40 similar to the light receiving surface electrode 12.

The high-density layer 72 is a layer in which a deeper, darker image than the low-density layer 73 is obtained in the cross sectional observation image using the SEM. In other words, in the SEM image, a degree of scattering and absorption of an electron beam differs in proportion to the difference in the density, and the portion of high density is darker because the transmissivity of the electron beam is low. In the SEM image of the high-density layer 72, in approximately the entire region of the observation cross section, the shading of the contrast is repeated in one direction, and a band shape appears. Such a boundary of contrast shading shows the crystal grain boundary. In the SEM image of the low-density layer 73, the portion where the contrast shading is repeated in one direction is less than 50%, and in some cases the portion where the contrast shading is regularly repeated cannot be recognized.

In the transparent conductive layer 71, the high-density layer 72 is provided in a wider range than the low-density layer 73. The low-density layer 73 is preferably selectively provided, on the surface of the transparent conductive layer 71, in the contact surface R which is a contact portion with the collecting electrode and the region immediately below of the contact surface R (hereinafter, also referred to as “contact surface region”). In addition, the low-density layer 73 is preferably not provided at the portion other than the contact surface region, where the solar light is received. In other words, the transparent conductive layer 71 in the contact surface region has a layered structure of the high-density layer 72 and the low-density layer 73, and the other portions of the transparent conductive layer 71 have a single-layer structure formed only with the high-density layer 72.

In the present embodiment, the composition of the high-density layer 72 is crystallized TCO, and the composition of the low-density layer 73 is a reduction product of the TCO. For example, when the TCO is a metal oxide having the primary composition of indium oxide (In₂O₃), the composition of the low-density layer 73 is indium oxide richer in indium compared to In₂O₃ forming the portions other than the contact surface region, or In.

A thickness of the transparent conductive layer 71 is preferably in a range of about 30 nm-500 nm, and particularly preferably in a range of 50 nm-200 nm. A thickness of the low-density layer 73 is preferably thinner than a thickness of the high-density layer 72. More specifically, a ratio of the thickness of the low-density layer 73 with respect to the thickness of the high-density layer 72 (thickness of the low-density layer 73/thickness of the high-density layer 72) is preferably in a range of about 0.2-0.8, and particularly preferably in a range of about 0.3-0.6. For example, the thickness of the high-density layer 72 is 80 nm and the thickness of the low-density layer 73 is 20 nm. The thicknesses are average values of the lengths along the thickness direction measured by a cross sectional observation using the SEM.

In the transparent conductive layer 71, the thickness of the portion where the low-density layer 73 is formed is thinner than the thickness of the other portions. In other words, in the transparent conductive layer 71, the portion where the reduction process of the TCO is applied is made thin.

The low-density layer 73 may exist over approximately the entirety of the contact surface R, or a part thereof. When the low-density layer 73 exists on a part of the contact surface R, that is, when the high-density layer 72 and the low-density layer 73 exist on the contact surface R, the area of the low-density layer 73 is preferably 20%-80% of the area of the contact surface R, and particularly preferably 25%-75% of the area of the contact surface R. In addition, the low-density layer 73 preferably exists evenly and uniformly in the contact surface R.

In the transparent conductive layer 71, a sheet resistance of the low-density layer 73 is higher than a sheet resistance of the high-density layer 72. The sheet resistance of the low-density layer 73 is, for example, higher by a factor of 1.05 times-5 times compared to the sheet resistance of the high-density layer 72. The sheet resistance may be measured through a known method (for example, a four-point probe method).

The sheet resistance of the contact surface region may be high. This is because the carriers flowing to the collecting electrode can be collected in the immediately below region Z of the side surface 31z of the collecting electrode, of the transparent conductive layer 71.

With reference to FIG. 11, a manufacturing process of the solar cell 70 having the above-described structure will now be described in detail. FIG. 11 is a diagram showing an example manufacturing process of the solar cell 70. Here, it is assumed that the collecting electrode is formed through two electroplating steps, including the nickel plating step and the copper plating step using the coating layer 14 as a mask, and the bus bar section 42 is formed through screen printing using a conductive paste.

Here, after the TCO layer having the single layer structure is formed, a reduction process is applied to the TCO layer to form the low-density layer 73. The high-density layer 72 is formed during the film formation of the TCO layer. However, the formation method of the high-density layer 72 and the low-density layer 73 is not limited to such a configuration. For example, the high-density layer 72 may be formed by thermally treating the TCO layer having the high-density layer 72 after the low-density layer 73 is formed.

In the manufacturing process of the solar cell 70, first, the photoelectric conversion unit 11 is manufactured through a known method (the manufacturing process of the photoelectric conversion unit 11 will not be described in detail). When the photoelectric conversion unit 11 is prepared, the light receiving surface electrode 12 is formed over the light receiving surface of the photoelectric conversion unit 11, and the back surface electrode 13 is formed over the back surface of the photoelectric conversion unit 11. In the example configuration of FIG. 11, a transparent conductive layer 71a which is a precursor of the transparent conductive layer 71 is formed over the light receiving surface of the photoelectric conversion unit 11, and then the transparent conductive layer 40 is formed over the back surface of the photoelectric conversion unit 11. Then, the metal layer 41 is formed over the transparent conductive layer 40 (FIG. 11(a)). The transparent conductive layers 71a and 40 can be formed, for example, through chemical vapor deposition (CVD). The film formation by CVD is preferably executed under temperature conditions of about 200° C.-300° C., and the TCO is crystallized by the heat, and the high-density layer 72 is formed. The metal layer 41 may be formed, for example, through sputtering. FIGS. 11(b)-11(d) show a mask formation step, a low-density layer formation step, and an electroplating step, respectively. In the mask formation step, a coating layer 14 made of a photo-curing resin is formed as a mask over the transparent conductive layer 71a. In the mask formation step, for example, a patterned coating layer 14 is formed over the entire region of the light receiving surface. The patterned coating layer 14 may be formed through a known method. For example, the patterned coating layer 14 may be formed by forming a thin film layer made of a photo-curing resin over the light receiving surface through spin coating, spraying, or the like, and then applying a photolithography process. Alternatively, the patterned coating layer 14 may be formed through printing such as screen printing.

The coating layer 14 is patterned to expose, on the surface of the transparent conductive layer 71a, the surface Ra which is the portion over which the collecting electrode is to be formed (surface Ra to become the contact surface R). In other words, an opening 33 corresponding to the contact surface R is formed in the coating layer 14. The coating layer 14 also functions as a mask in the low-density layer formation step.

The low-density layer formation step is provided between the mask formation step and the electroplating step. The low-density layer formation step is a step in which the TCO in the surface Ra of the transparent conductive layer 71a formed with the high-density layer 72 exposed from the opening 33 is reduced, to form the low-density layer 73. When the TCO is reduced, in the initial stage of the reduction, an amount of oxygen of the TCO is reduced and the sheet resistance is reduced, but in the present step, the reduction proceeds further. With such a process, the sheet resistance becomes higher than that before the reduction, and the low-density layer 73 is formed in the surface Ra and an immediately below region thereof. For example, when the TCO is indium oxide (In₂O₃), the low-density layer 73 in which a ratio of indium (In) is increased is formed. In this manner, the transparent conductive layer 71 having the high-density layer 72 and the low-density layer 73 is formed.

A method of the reduction process is not particularly limited so long as the TCO at the surface Ra can be selectively reduced and the low-density layer 73 can be formed. For example, reduction by a hydrogen plasma process or electrolytic reduction may be employed. The former is a gas phase reduction and the latter is a liquid phase reduction. When the electrolytic reduction is executed, for example, an aqueous solution of ammonium sulfate is used for the electrolytic solution, the photoelectric conversion unit 11 over which the coating layer 14 is formed is used as the cathode, and a platinum plate is used as the anode. The photoelectric conversion unit 11 and the platinum plate are immersed in the electrolytic solution, and a current is applied therebetween. To the photoelectric conversion unit 11, for example, a negative electrode of a power supply device is connected to a part of the surface Ra exposed from the opening 33.

The thickness and the area in the contact surface R of the low-density layer 73 can be adjusted by, for example, an amount of applied current (current×time). Normally, as the amount of current is increased, the thickness and the area in the contact surface R of the low-density layer 73 are increased.

In the electroplating step, the electroplating is executed using the photoelectric conversion unit 11 over which the coating layer 14 is used as the cathode and a nickel plate is used as the anode. A negative electrode, for example, of a power supply device is connected to the photoelectric conversion unit 11 at a part of a surface Rb of the transparent conductive layer 71 exposed from the opening 33. The electroplating is executed in a state where the back surface is insulated and covered so that the metal plated layer is not deposited over the back surface of the photoelectric conversion unit 11 (for example, an insulating resin layer covering the back surface is formed and then removed after the electroplating step), by immersing the photoelectric conversion unit 11 and the nickel plate in a plating solution, and applying a current therebetween. For the plating solution, a known nickel plating solution containing nickel sulfate or nickel chloride may be used. In this manner, a nickel plated layer is formed over the surface Rb exposed from the opening 33 and in which the low-density layer 73 is formed.

Then, electroplating is applied using a copper plate as the anode and a known copper plating solution containing copper sulfate or copper cyanide. With this process, a copper plated layer is formed over the nickel plated layer which is formed earlier, and the finger section 31 and the bus bar section 32 formed with the nickel plated layer and the copper plated layer are formed. Thicknesses of the metal plated layers are, for example, each about 30 μm-50 μm, and can be adjusted by an amount of applied current (current×time).

Then, the bus bar section 42 is formed over the metal layer 41 through screen printing (FIG. 9(e)). In the present step, after a conductive paste (for example, silver paste) is screen printed over the metal layer 41 in a desired pattern, a solvent contained in the paste is volatilized to form the bus bar section 42. The conductive paste contains, for example, a thermosetting binder resin such as an epoxy resin, a conductive filler dispersed in the binder resin such as silver or carbon, and the solvent such as butylcarbitolacetate (BCA). In other words, the bus bar section 42 is made of the binder resin in which the conductive filler is dispersed. When the solvent in the conductive paste is volatilized and the binder resin is thermoset, for example, a thermal treatment is applied under conditions of 200° C.×60 minutes.

Alternatively, the high-density layer 72 may be formed by the thermal treatment during the formation of the bus bar section 42. For example, the TCO layer is formed through sputtering (under a non-heated condition), and after the low-density layer 73 is formed in the manner as described above, the portions other than the low-density layer 73 may be crystallized by the thermal treatment, to form the high-density layer 72.

In this manner, the low-density layer 73 may be provided in the contact surface R of the transparent conductive layer 71 and the region immediately below, and a layered structure of the high-density layer 72 and the low-density layer 73 may be obtained. Because the contact strength between the low-density layer 73 and the collecting electrode is greater than the contact strength between the high-density layer 72 and the collecting electrode, according to the solar cell 70 having the low-density layer 73 in the contact surface R, the contact strength between the transparent conductive layer 71 and the collecting electrode can be improved.

On the other hand, the low-density layer 73 has a lower transparency than the high-density layer 72. However, because the low-density layer 73 is selectively provided only on the contact surface R due to the existence of the coating layer 14, generation of light reception loss due to the low-density layer 73 can be prevented.

In addition, because the collecting electrode is formed by electroplating, the solar cell 70 can be manufactured at a lower cost compared to the other methods (for example, sputtering or screen printing). Normally, the plated electrode is inferior in the contact characteristic with the transparent conductive layer compared to the electrodes formed through other methods, but according to the solar cell 70, the contact strength between the plated electrode and the transparent conductive layer 71 can be improved, and the peeling of the plated electrode can be sufficiently inhibited.

The above-described embodiments may be suitably modified in design within a scope of not losing the advantages of the present invention.

For example, in the above, configurations are described in which the particles 50 and 50x are deposited by a reduction process of the TCO, but alternatively, the particles may be added over the transparent conductive layer. In this case, as the particles, conductive nano-particles such as silver and nickel are preferably employed. For example, a dispersion solution in which the nano-particles are dispersed may be applied over the transparent conductive layer, and a structure in which the nano-particles are attached over the transparent conductive layer may be obtained.

In addition, in the above-described embodiments, configurations are described in which the finger section 31 and the bus bar section 32 are plated electrodes formed through electroplating, but alternatively, these sections may be electrodes formed through sputtering or screen printing.

Furthermore, the photoelectric conversion unit 11 may be suitably modified to structures other than the structure described above.

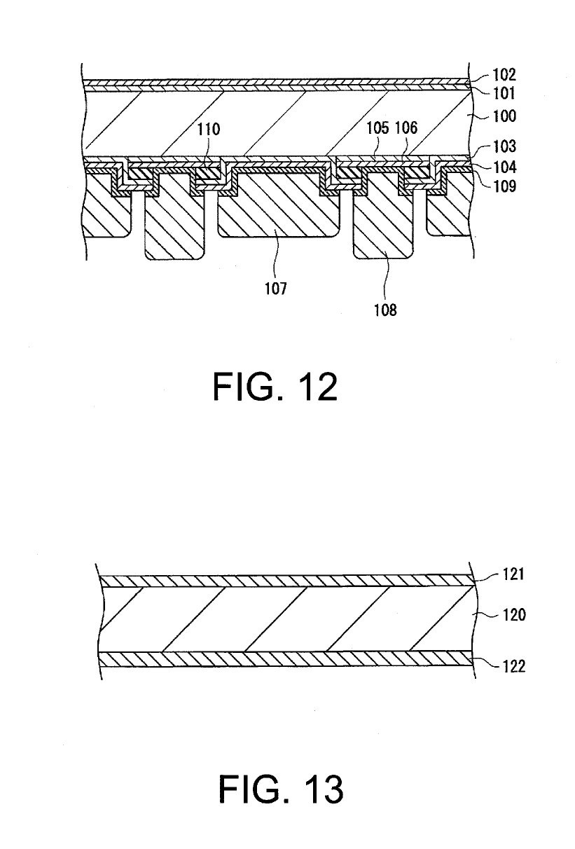

For example, as shown in FIG. 12, a structure may be employed in which an i-type amorphous silicon layer 101 and an n-type amorphous silicon film 102 are formed over the side of the primary surface of an n-type monocrystalline silicon substrate 100, and a p-type region, formed with an i-type amorphous silicon layer 103 and a p-type amorphous silicon layer 104, and an n-type region, formed with an i-type amorphous silicon layer 105 and an n-type amorphous silicon layer 106, may be formed over a side of the back surface of the n-type monocrystalline silicon substrate 100. In this case, the electrode is provided only on the side of the back surface of the n-type monocrystalline silicon substrate 100. The electrode includes a p-side collecting electrode 107 formed over the p-type region and an n-side collecting electrode 108 formed over the n-type region. A transparent conductive layer 109 is formed between the p-type region and the p-side collecting electrode 107, and between the n-type region and the n-side collecting electrode 108. An insulating layer 110 is provided between the p-type region and the n-type region.

Furthermore, as shown in FIG. 13, a structure may be employed in which the photoelectric conversion unit 11 is formed with a p-type polycrystalline silicon substrate 120, an n-type diffusion layer 121 formed over a side of a primary surface of the p-type polycrystalline silicon substrate 120, and an aluminum metal film 122 formed over a back surface of the p-type polycrystalline silicon substrate 120.

1. A solar cell comprising:
a photoelectric conversion unit;
a transparent conductive layer formed over a primary surface of the photoelectric conversion unit; and
a collecting electrode formed over the transparent conductive layer, wherein
the transparent conductive layer has particles on a surface thereof.

2. The solar cell according to claim 1, wherein
the transparent conductive layer is formed with a transparent conductive oxide, and
a composition of the particles is a reduction product of the transparent conductive oxide.

3. The solar cell according to claim 2, wherein
a particle diameter of the particles is greater than or equal to 10 nm and less than or equal to 200 nm.

4. The solar cell according to claim 1, wherein
the particles selectively exist in a contact portion with the collecting electrode, of the surface of the transparent conductive layer.

5. The solar cell according to claim 2, wherein
the particles selectively exist in a contact portion with the collecting electrode, of the surface of the transparent conductive layer.

6. The solar cell according to claim 3, wherein
the particles selectively exist in a contact portion with the collecting electrode, of the surface of the transparent conductive layer.

7. The solar cell according to claim 4, wherein
the particles exist uniformly over the entire region of the contact portion.

8. The solar cell according to claim 5, wherein
the particles exist uniformly over the entire region of the contact portion.

9. The solar cell according to claim 6, wherein
the particles exist uniformly over the entire region of the contact portion.

10. The solar cell according to claim 1, wherein
the particles exist in a higher density in a portion, of the surface of the transparent conductive layer, where a crystal grain boundary of the transparent conductive oxide is formed, than in the other portions.

11. The solar cell according to claim 2, wherein
the particles exist in a higher density in a portion, of the surface of the transparent conductive layer, where a crystal grain boundary of the transparent conductive oxide is formed, than in the other portions.

12. The solar cell according to claim 3, wherein
the particles exist in a higher density in a portion, of the surface of the transparent conductive layer, where a crystal grain boundary of the transparent conductive oxide is formed, than in the other portions.

13. The solar cell according to claim 4, wherein
the particles exist in a higher density in a portion, of the surface of the transparent conductive layer, where a crystal grain boundary of the transparent conductive oxide is formed, than in the other portions.

14. The solar cell according to claim 5, wherein
the particles exist in a higher density in a portion, of the surface of the transparent conductive layer, where a crystal grain boundary of the transparent conductive oxide is formed, than in the other portions.

15. The solar cell according to claim 6, wherein
the particles exist in a higher density in a portion, of the surface of the transparent conductive layer, where a crystal grain boundary of the transparent conductive oxide is formed, than in the other portions.

16. The solar cell according to claim 7, wherein
the particles exist in a higher density in a portion, of the surface of the transparent conductive layer, where a crystal grain boundary of the transparent conductive oxide is formed, than in the other portions.

17. The solar cell according to claim 8, wherein
the particles exist in a higher density in a portion, of the surface of the transparent conductive layer, where a crystal grain boundary of the transparent conductive oxide is formed, than in the other portions.

18. The solar cell according to claim 9, wherein
the particles exist in a higher density in a portion, of the surface of the transparent conductive layer, where a crystal grain boundary of the transparent conductive oxide is formed, than in the other portions.
